(19) United States
(12) Patent Application Publication
(10) Pub. No.: US 2009/0320896 A1
(43) Pub. Date: Dec. 31, 2009

(54) Moisture resistant solar panel and method of making same

(76) Inventor: Peter F. Gerhardinger, Maumee, OH (US)

Correspondence Address: MARSHALL & MELHORN, LLC, FOUR SEAGATE - EIGHTH FLOOR, TOLEDO, OH, 43604, US

(21) Appl. No.: 12/456,626

(22) Filed: Jun. 19, 2009

Related U.S. Application Data
(60) Provisional application No. 61/133,004, filed on Jun. 25, 2008.

(51) Int. Cl. H01L 31/042; H01L 31/18; B32B 17/06

(52) U.S. Cl. 136/244; 438/73; 428/212; 257/E31.11

(57) ABSTRACT

The present invention relates to a solar panel assembly which is particularly impervious to moisture due, primarily, to the nature of the materials forming the coverplate and the base member of the solar panel assembly, namely a transparent glass, and a flexible metal, respectively. The flexibility of the base member also facilitates the deposition of a photovoltically functional coating thereon.

### RELATED APPLICATION

This application is claiming the benefit, under 35 U.S.C. 119(e), of the provisional application filed Jun. 25, 2008 under 35 U.S. C. 111(b), which was granted Ser. No. 61/133,004. This provisional application is hereby incorporated by reference.

### BACKGROUND

The invention relates to a solar panel, more particularly, to a solar panel which is highly weather resistant, but which can be made cost effectively.

It is known to make solar panels using a glass coverplate, however, such glass coverplates have, typically, been combined with complex backing structures, sometimes made of relatively heavy gauge, rigid metal, or other materials exhibiting similar properties. As a result, the functional coating layers are, generally, deposited on the glass coverplate, sometimes referred to as a superstrate. Solar panels made according to such a design, while relatively robust, are also relatively expensive.

Laminated glass photovoltaic devices are known which, typically, include a glass coverplate with edge-deleted photovoltaically functional thin film layers and bus bars deposited thereon. A base glass sheet, often having one or more holes drilled therein to facilitate electrical connection with the bus bars, is laminated to the coverplate via an EVA interlayer under appropriate conditions of temperature and pressure.

It is also known to make so-called “flexible” solar panels often made with a transparent polymeric coverplate and a non-transparent polymeric or metal, base element. In solar panels of this type of structure, the functional coating layers are, typically, deposited on the base element. In the case of a flexible metal base element, such coating operations can be done in a continuous operation, such as is disclosed in U.S. Pat. No. 5,092,939. It is well known, however, that such flexible solar panels are prone to penetration by moisture, even through the polymeric materials. Also, the polymeric coverplates are subject to mechanical and chemical weathering by the natural elements and man-made contaminants contained therein. Such weathering clearly can degrade the performance of the solar panel.

Solar panels of many designs are described in the patent literature, for example:

U.S. Pat. No. 5,092,939 describes a roof structure comprising panels of a desired length each having a galvanized steel supportive layer which has side supporting flanges interconnected to form the roof assembly. The mid portion of each panel has a photovoltaic surface made from amorphous semiconductor material which is laminated onto the galvanized steel with a protective transparent polymer coating laminated above the photovoltaic material.

U.S. Pat. No. 5,768,831 describes a roofing system serving as a carrier for a solar panel with photovoltaic solar cells to be attached to its upper side where the solar panel is attached form-fittingly to the upper side of the roofing system.

U.S. Pat. No. 6,207,603 describes a borosilicate glass having properties that enable it to be drawn as microsheets for use as a solar cell cover glass and a solar cell having such microsheet as a cover glass, the glass having a defined composition.

U.S. Pat. No. 6,291,672 describes a photovoltaic module said to be dustproof and weather resistant comprising: (a) a front substrate which is a light transmittable safety glass plate on which a photo-catalyst is applied; (b) a back substrate which is a polyester polymer membrane and (c) a photosensitizer located between the front and back substrates, which comprises electrical circuit copper foils and polymeric enclosing material (EVA).

U.S. Pat. No. 6,407,327 describes a modular glass covered solar cell array including at least-physically and electrically interconnected solar cells. At least a portion of both cells are covered by a common, substantially transparent cover, which transparency is said not to degrade when exposed to a space radiation environment.

U.S. Pat. No. 6,653,553 describes a cover constructed as a solar generator for closing an opening in the body-work of a vehicle which consists of a transparent panel, an assembly attached to the underside of the panel, which assembly consists of a solar cell field and a plastics material in which the latter is embedded, a frame foamed into the peripheral edge area of the panel, and a foam-molded backing layer connected in one piece with the frame.

U.S. Pat. No. 6,667,434 describes a solar cell module including a plurality of solar cell elements sealed by EVA resin between a front surface glass and a rear surface member provided with a sodium diffusion-preventing layer of a PET film of a smaller water vapor transmission rate than those of the EVA sheets interposed between the front surface glass and the solar cell elements.

U.S. Pat. No. 6,818,819 describes a solar cell module which is said to reduce water reaching a front surface glass by using a rear surface member of a resin film so as to suppress sodium leached from the front surface glass from reaching the front surface of the solar cell element. The solar cell module comprises a front surface glass, a rear surface resin film, a plurality of solar cell elements sealed with sealing resin between the front surface glass and the rear surface resin film, and a water transmission-preventing layer arranged in a position including at least an interval part between the solar cell elements adjacent each other.

U.S. Published Patent Application No. 2007/0134501 describes a process for preparing a self-cleaning coating on a substrate such as glass comprising providing a coating composition, adding to the coating composition nanocrystals of a photoactive material, and applying the mixture of coating composition and photoactive material to a surface of a substrate at an elevated temperature, to deposit a self-cleaning coating on the surface of the substrate. A solar thermal device comprises a solar energy conversion device, including a transparent substrate, and a self-cleaning coating adhered to the surface of the substrate.

### BRIEF DESCRIPTION OF THE DRAWINGS

Further details and advantageous features of the invention are set forth in the following description and associated drawings.

FIG. 1 is a cross-sectional view of the basic components of a solar panel according to the invention in a non-assembled state.

FIG. 2 is a cross-sectional view of the solar panel of the invention in an operational configuration.

FIG. 3 is a cross-sectional view of an embodiment of a solar panel according to the invention wherein the glass coverplate is laminated to the base member by a polymeric layer.

FIG. 4 is a plan view of the solar panel of the invention including conductive bus bars.

FIG. 5 is a cross-sectional view of an embodiment of the invention wherein a polymeric seal/frame helps to seal the solar panel and to affix the coverplate and base member to one another.

FIG. 6 is a cross-sectional view of the solar panel of the invention including a peripheral frit band and anti-reflective coating on the glass coverplate.

FIG. 7 is a partial, perspective view of a solar panel in accordance with the invention as well as certain details of a means of connecting the solar panel to an electrical device/system.

FIG. 8 is a cross-sectional view of an exemplary means of connecting multiple solar panels according to the invention.

FIG. 9 is a cross-sectional view of an insulated glass unit incorporating a solar panel of the present invention as a component thereof.

### SUMMARY OF THE INVENTION

The present invention relates to a solar panel assembly and a method of making same, which solar panel is particularly resistant to penetration by moisture, in whatever form, due primarily to the nature of the materials forming the base member and the coverplate, both of which are, for all practical purposes, impervious to moisture, while at the same time, the coverplate allows a high percentage of total solar radiation to penetrate to the photovoltaically functional materials preferably deposited on the base member while providing beneficial structural strength. The base member also is of sufficient flexibility to allow for the deposition of the photovoltaically functional materials thereon by a cost-effective coating process facilitated by the flexibility of the material of the base member. The base member and the coverplate are adhesively bonded to one another to form a highly moisture resistant solar panel assembly. An electrically conductive structure is present on the base member or the coverplate to allow the electrical energy generated by the solar panel to be transmitted to a device or to, for example, an electrical distribution system.

### DETAILED DESCRIPTION OF THE INVENTION

The present invention relates to a solar panel assembly, and a method of making same, which for reasons to be discussed in greater detail hereafter, is resistant to damage by the natural elements, such as precipitation in whatever form, windborne particulate matter having, for example, abrasive effects, deposition of organic matter from vegetation and animals, as well as man-made contaminants. Thus, degradation of the conversion of solar radiation to electrical energy by the solar panel due to even long term exposure to such contaminants, as noted above, is greatly reduced relative to known solar panels. Additionally, due to the relatively inexpensive materials utilized in its construction, and the relatively simple assembly process utilized to produce the subject solar panel, it can be produced very cost-effectively. Conversion efficiency is also quite good.

The solar panel assembly 10 of the present invention is comprised of two major components, a base member 14 formed from a flexible, moisture impervious material, and a coverplate 12 formed from a transparent water impervious glass. Preferably, one or more layers of photovotaically functional material 16 is/are deposited on the base member 14. At least one electrically conductive structure 18, for example, one or more bus bars 18 are formed on either the base member 14 or the coverplate 12, preferably the coverplate 12. An electrical connector 26, is attached, by a suitable method, to the electrically conductive structure 18 to enable connection to, for example, an electrically powered device or to an electrical transmission/distribution system.

The base member 14 can be any suitable material which is impervious to moisture, that is, having a permeability of less than 1×10⁻²¹ cm/sec., has a 0.2% yield strength of at least 205 MPa, and preferably is highly corrosion resistant. Materials meeting this description include, but are not limited to, stainless steels, particularly 308, 316, 329, and 330 stainless steels, and the like. For purposes of this application, the term “yield strength” means the unit stress corresponding to a specific amount of permanent unit deformation, specifically, 0.2% deformation. The “300 series” of stainless steels is resistant to a wide variety of types of corrosion, such as mild atmospheric and fresh water, atmospheric industrial and marine, chemical (oxidizing and reducing), which could be experienced in terrestrial deployment of solar panels of the present invention.

In the solar panel 10 of the present invention it is preferred to deposit, by any suitable method, one or more photovoltaically functional thin-film coatings 16 on the base member 14. Suitable coating methods, when the base member 14 is flexible stainless steel of the type previously described herein, include methods such as vacuum deposition methods, chemical vapor deposition, spray pyrolysis, physical vapor deposition and combinations thereof. Preferred coating methods include processes where the flexibility of the base member 14 material allows it to be coated with the photovoltaically functional thin films 16 in a continuous manner, analogous, for example, to vacuum deposition of photovoltaically functional and/or electrically conductive thin films on flexible, transparent polymeric materials. Suitable photovoltaically functional coatings 16 include but are not limited to known thin P-I-N thin films, for example amorphous silicon, germanium, copper indium diselenide, copper indium gallium selenide, and cadmium telluride. While it is within the scope of the invention to utilize a lamination process such as is described in U.S. Pat. No. 5,092,939 to adhere a coated polymeric film to the stainless steel substrate, it is preferred to deposit the photovoltaically functional layer directly on the stainless steel substrate, as direct deposition eliminates a process step (bonding the polymeric film to the stainless steel) as well as the cost of the polymeric material.

The glass coverplate 12 of the present invention can be formed from any suitable glass. Preferably, the glass is of a soda-lime-silica composition made in the well known float glass process. Clear, soda-lime-silica float glass of 3-4 mm in thickness is particularly preferred, as it is relatively inexpensive, and is highly transparent to total solar radiation, but does absorb some potentially degrading UV radiation. Such glasses are inherently impervious to moisture and are chemically inert, as well as being abrasion resistant and providing substantial structural strength to the completed solar panel assembly. So-called low-iron glass may also be used. It is also preferred that the glass of the coverplate be tempered, also known as toughened. In addition to the properties of glass noted above, tempered glass is highly resistant to impact from, for example, hail stones and other types of natural or human-caused impacts, thus allowing the solar panel assembly of the present invention to meet applicable standards for preventing injury to people who may come in contact with the subject assemblies. Tempered glass is also resistant to thermal stresses.

Utilizing glass as a coverplate 12 also allows an electrically conductive structure 18, for example one or more bus bars, to be deposited thereon, preferably on a major surface, often referred to as the #2 surface; that, is the surface closest to the base member, the #1 surface being the major glass surface exposed to the environment. Since glass can withstand relatively high temperatures, it is possible to utilize cost-effective methods such as chemical vapor deposition or spray pyrolysis, in addition to vacuum sputtering techniques, to deposit the electrically conductive structures 18. Metals such as silver and copper are often deposited in predetermined patterns to form bus bars 18 on glass.

It is also possible to deposit the photovoltaically functional thin-film coatings 16 on the #2 surface of the glass coverplate by off-line, or on-line (during the float glass manufacturing process) pyrolytic vapor deposition processes. Similarly, it is possible to deposit thin-film coatings 24 exhibiting, for example, photocatalytic or anti-reflective properties on the #1 surface of the glass coverplate 12 of the invention.

Any conventional means may be utilized to electrically connect the subject solar panel 10 to, for example, an electrically powered device, to an electrical transmission or distribution system, a DC to AC inverter and electric energy storage devices such as batteries. Such means include, for example, wires, cables, conductive tape and metallic bus bars. Of course, multiple solar panels 10 may be electrically connected to one another and the cumulative electrical power generated is transmitted in ways similar to those described above for a single solar panel of the invention.

In addition to the moisture impervious nature of the material of the base member 14 and the coverplate 12, it is desirable to affix those two components one to the other, in a manner that will enhance the moisture imperviousness of the solar panel assembly 10. A preferred affixation method is to adhesively bond the base member 14 and the glass coverplate 12 by a transparent adhesive. For some applications, an electrically conductive adhesive may be advantageous. Alternatively, a self-adhering polymeric interlayer 17, such as polyvinyl butyral (PVB) or EVA or combinations thereof, may be inserted between the base member 14 and coverplate 12. When exposed to proper conditions of temperature and pressure, the two components are bonded together by the now-transparent polymeric interlayer 17 to form a laminated structure.

In one embodiment, a polymeric seal or gasket 22 may be molded around a portion of, or the entire periphery of, the solar panel 10 to affix the base member 14 and the coverplate 12 to one another. Such polymeric gasket 22 may be formed by any suitable molding technique, for example, injection molding or reaction injection molding (RIM). Injection molding of polyvinyl chloride (PVC) to form the seal 22 is a cost effective molding method in accordance with the invention.

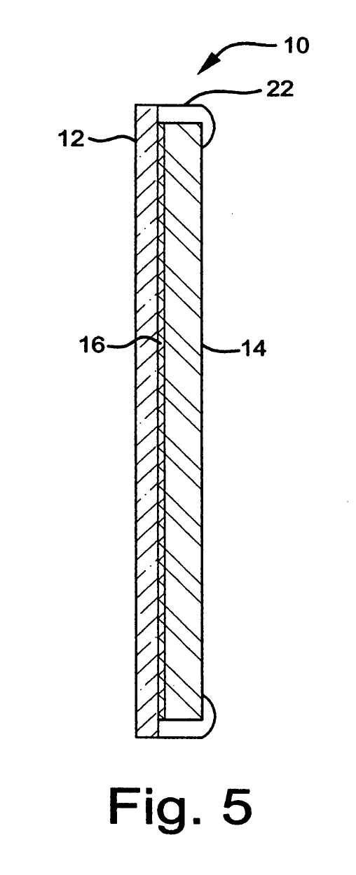

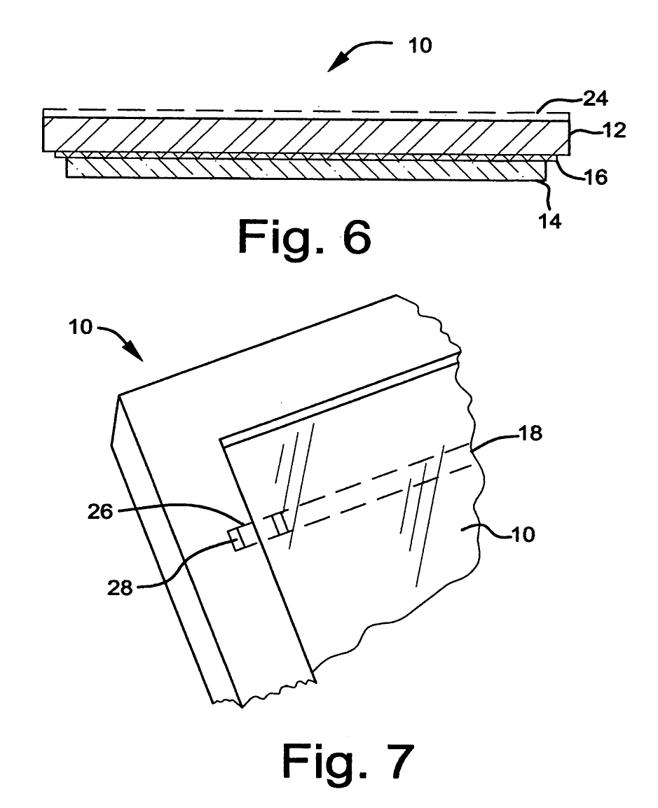

In a preferred configuration, the glass coverplate 12 is of larger dimension than the base member 14, as shown in FIGS. 5 and 6. When the molding process is conducted, the outer surface of the seal or gasket 22 is coplanar with the #1 surface of the coverplate 12, so as to present a “flush” appearance, or may contact the #2 surface of the coverplate 12 as shown in FIG. 5.

As previously described herein, the solar panel coverplate 12 of the present invention, preferably being of tempered glass, provides excellent weatherability and durability. The glass of the coverplate 12 suffers minimal degradation when subjected to various recognized testing methods for, for example, abrasion resistance, humidity resistance, thermal stress, and chemical resistance. Such testing methods are set forth in, for example, DIN Standard EN-1096-2, ISO 9211-4, ISO 9022-2, and ISO 9022-4. In particular, the glass coverplate of the present invention preferably exhibits no more than 2% haze after being subjected to 1000 Taber abrader cycles as set forth in ASTM Standard D1044, the haze being measured on a Gardner Hazegard device.

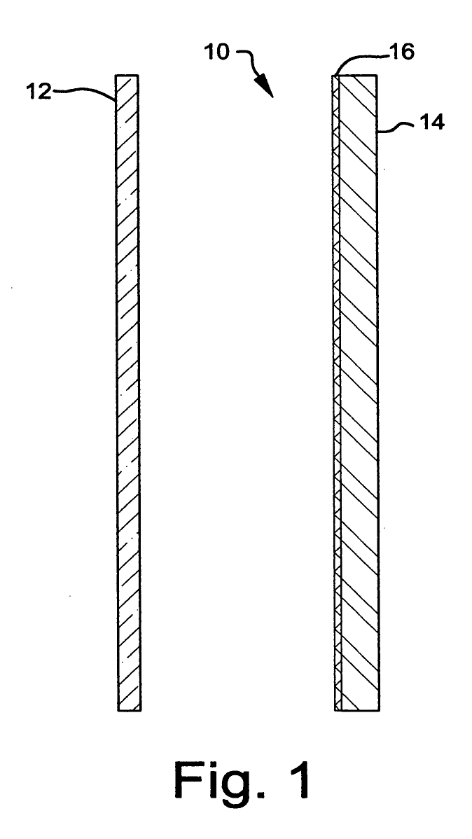

Turning now to the Figures, FIG. 1 shows the basic components of the inventive solar panel 10 prior to assembly, more specifically a glass coverplate 12, preferably of clear float glass, at a thickness of 3-4 mm, although other suitable types of glass at other thicknesses may also be used. Also illustrated is a base member 14 having one or more photovoltaically functional coatings 16 disposed thereon. The base member 14 is of a flexible metal, preferably stainless steel, the flexibility of which is as defined elsewhere herein.

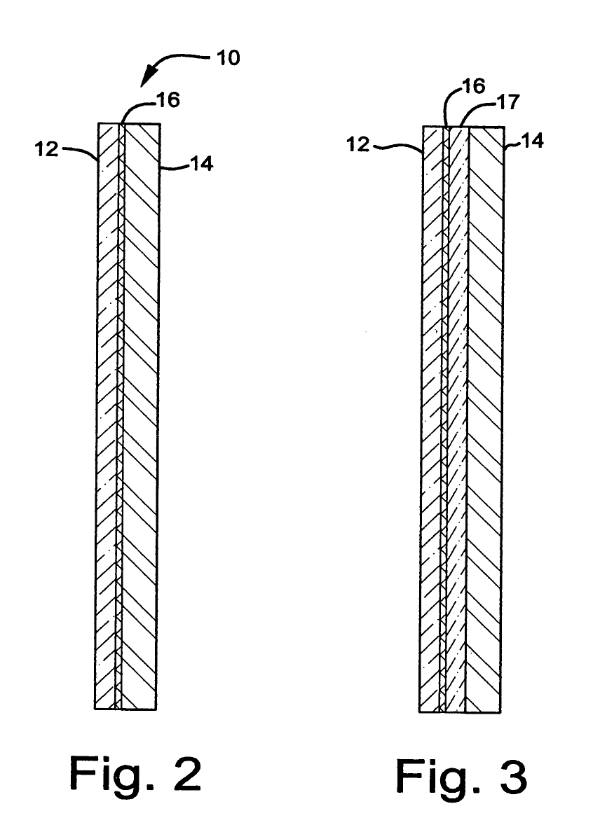

FIG. 2 shows the basic components of FIG. 1 assembled into a solar panel unit 10 of the present invention. Various means of bonding the coverplate 12 and base member 14 are possible, including transparent and/or electrically conductive adhesives.

FIG. 3 shows a solar panel assembly 10 of the present invention in a variant of the assembly of FIG. 2, wherein the coverplate 12 and base member 14 are bonded together by a lamination process. That is, a self-adhering interlayer material 18, placed between the coverplate 12 and the base member 14, is subjected to temperature and pressure sufficient to cause the interlayer to adhesively bond to both the coverplate and the base member, creating a highly water resistant solar panel assembly. Various arrangements of the photovoltaically functional coating and electrically conductive elements of the assembly are possible, for example, utilization of an electrically conductive adhesive applied between bus bar elements and the flexible base member, in combination with a double faced tape affixed to a peripheral portion of the glass coverplate, and possibly application of a resin material.

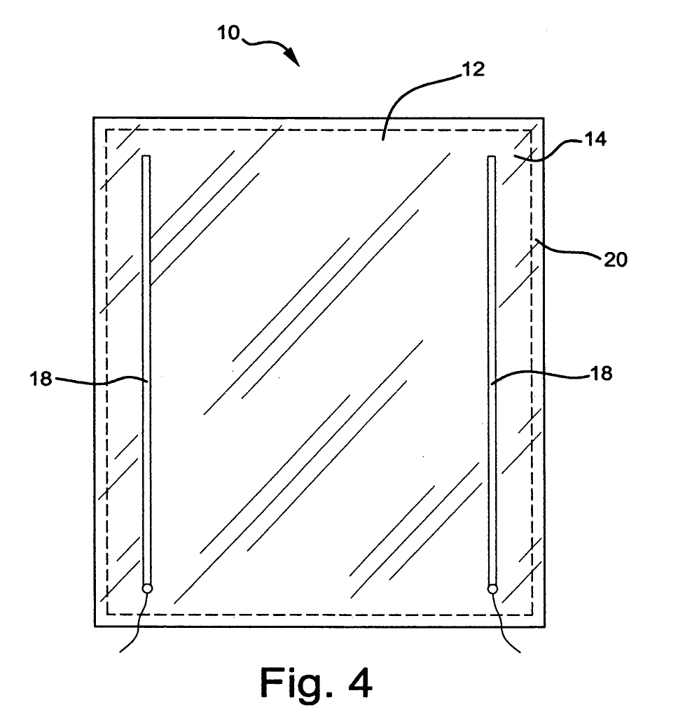

FIG. 4 is a plan view of a solar panel 10 of the invention as shown in cross-section in FIG. 6. The electrically conductive structure 18, preferably one or more bus bars 18, are shown in a conventional straight-line configuration, although other predetermined patterns are within the scope of the invention. An obscuration band 20 such as shown, may be disposed on all, or a portion of, the periphery of the #2 surface of the coverplate, primarily for aesthetic purposes. A ceramic frit or other opaque material may be disposed by any suitable method on the coverplate 12 to form the obscuration band 20.

FIG. 5 illustrates an optional means of enhanced sealing of the periphery of the solar panel assembly 10 of the present invention by molding onto the assembly a frame or gasket 22 comprising a polymeric material. Other gasket 22 profiles than that shown in FIG. 5 are within the scope of the invention.

FIG. 6 shows the solar panel 10 of the invention as shown in plan view in FIG. 4. Additionally, a coating 24 comprising one or more layers is shown on the #1 surface of the coverplate 12. While such a coating 14 may perform one or more functions, such coating 24 may be, for example, a photocatalytic, or “self-cleaning” coating, an electrically conductive coating, or an anti-reflective coating.

FIG. 7 shows a portion of a solar assembly 10 of the invention illustrating one possible means of transmitting electricity conducted by a bus bar 18 to a soldered, or otherwise bonded, electrical connector 26, thence to a tab 28 which will accept, for example, a push-on connector.

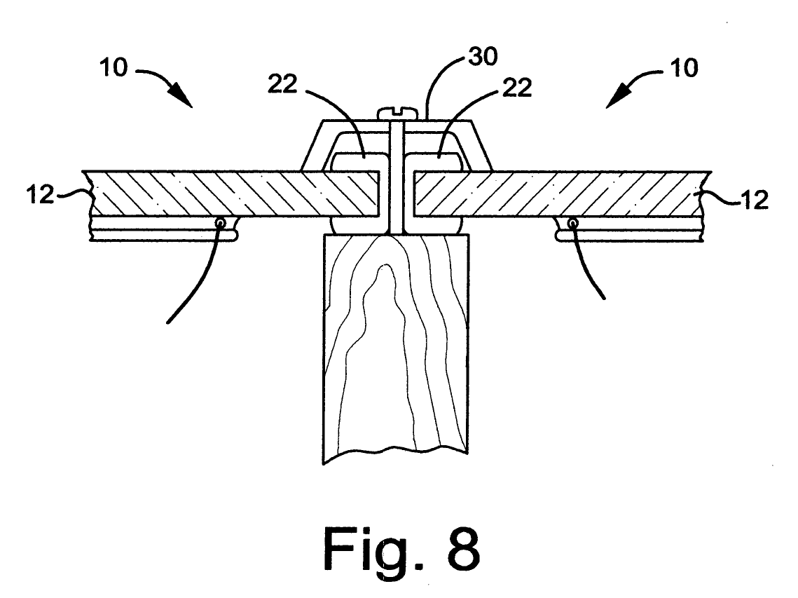

FIG. 8 shows a connector block 30 configuration suitable for connecting two solar panels 10 of the present invention. Utilization of multiple such connector blocks 30 will allow creation of a solar panel array comprising a plurality of the inventive solar panels 10.

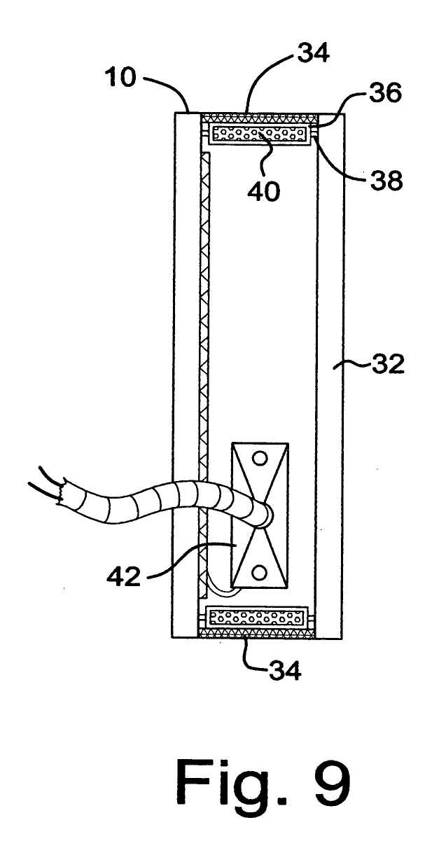

FIG. 9 shows a cross-sectional view of a solar panel of the present invention (as illustrated in FIG. 6) which has been incorporated as a component of an insulated glass unit. The solar panel as discussed in connection with FIG. 6 has a portion of, or the entire periphery thereof, which has been “edge deleted” so as to act as a “mounting flange” for a frame member 34, a spacer 36 and one or more seal members 38 to be bonded thereto, and then this assembly to be brought into a bonded parallel, spaced apart relationship with a second sheet of glass 32, in any suitable manner known to those skilled in the art of constructing insulated glass units. Optionally, a desiccant material 40 may be included in the frame 34 and/or spacer 36.

Also, due to the potentially high voltages resulting from the connection of multiple solar panels of the invention, a suitable fitting 42, such as that disclosed in U.S. Patent Publication No. 20070204531 may be utilized in connection with such an insulated glass unit.

While various methods of manufacturing the solar panel of the present invention are possible, including conventional manufacturing/assembly methods, for example at a single centralized facility, the novel components which comprise the present solar panel also allows for more de-centralized methods of manufacturing/assembly to be very cost-effectively utilized.

One such possible method of manufacturing/assembly allows, for example, a multi-region manufacturing/assembly and distribution network. More particularly, at a first location, a continuous ribbon of a flexible metal material, which will become a base member of a subject solar panel, is coated by any suitable deposition method with one or more coating materials which individually or collectively form a photovoltaically functional coating thereon. The continuous ribbon of flexible metal material is, preferably, made at the first location, but could be made elsewhere, and transported to the first location. The flexible metal material and the photovoltaically functional coating or coating stack may be any suitable material, as defined elsewhere herein.

The continuous ribbon of coated flexible metal material is then, preferably, cut into ribbons of a predetermined length, which are formed into rolls, which are readily transportable. The rolls of coated, flexible metal material are transported to at least a second location, but preferably multiple locations, geographically selected to be nearer to customers for such solar panel assemblies than the first location.

At such at least second location, the rolls of coated, flexible metal material received from the first location are further processed by, at least, cutting the coated, flexible metal material into lengths suitable for forming a base member of a solar panel assembly according to the invention, and adhesively affixing same to a transparent coverplate, according to the invention, as described elsewhere herein. At least one electrical connection is, preferably, attached to the base member/coverplate assembly, so as to provide electrical connectivity at least with the photovoltaically functional coating to form a functional solar panel assembly.

In a preferred aspect of the method, the functional solar panel assembly is transported to a third location where the solar panel assembly is installed and begins operating for its intended purpose of converting solar radiation to electrical energy. It is also possible, however, that such third location may be a seller/distributor of solar panel assemblies, or the like.

As previously described herein, it is within the scope of the invention that the solar panel assembly may be a laminated structure, or an insulated glass unit (IGU). Consequently, other processes necessary to construct laminated or IGU solar panel assemblies may be performed at the first and/or second locations of the manufacturing/assembly method just described.

Those skilled in the art of solar panel assemblies will appreciate that the present solar panel assembly has the advantage of so-called flexible solar panels in terms of ease of manufacturing, but due to the moisture resistance materials chosen, and the structural strength of the glass coverplate, as well as the other protective benefits of the glass coverplate over other types of materials in known solar panel coverplates, has many advantages over the known solar panel assemblies.

The foregoing specific advantages and description of the invention are illustrative of those that can be achieved by the present invention and are not intended to be exhaustive or limiting of the possible benefits which can be realized. Variations of the present invention are possible without departing from its spirit and scope as defined by the appended claims.

What is claimed is:

1. A solar panel assembly comprising:
a base member having a permeability of less than 1×10⁻²¹ cm/sec. and a 0.2% yield strength of at least 205 MPa;
one or more layers of photovoltaically functional material disposed on the base member; and
a coverplate of a transparent material having a permeability of less than 10⁻²¹ cm/sec., a total solar radiation transmittance >80% and a UV transmittance of no more than 70%, adhesively bonded to the base member upon which the photovoltaically functional layers have been deposited.

2. The solar panel defined in claim 1, wherein the material of the base member comprises a metal.

3. The solar panel defined in claim 2, wherein the material of the base member comprises stainless steel.

4. The solar panel defined in claim 1, wherein the transparent material of the coverplate comprises glass.

5. The solar panel defined in claim 4, wherein the transparent material of the coverplate comprises clear soda-lime-silica glass made by the float glass process.

6. The solar panel defined in claim 4, wherein the transparent material of the coverplate comprises a low iron glass.

7. The solar panel defined in claim 4, wherein the glass of the coverplate is toughened glass.

8. The solar panel defined in claim 1 further comprising a sealing structure bonded to, and surrounding at least a portion of, the periphery of one or both of, the base member and the transparent coverplate.

9. The solar panel defined in claim 4, wherein electrically conductive structures are disposed on the major surface of the glass coverplate nearest to the base member.

10. The solar panel defined in claim 4, wherein the electrically conductive structures comprise one or more bus bars.

11. The solar panel defined in claim 1, wherein the base member and the transparent coverplate are bonded to one another with a transparent adhesive material.

12. The solar panel defined in claim 11, wherein the adhesive comprises an electrically conductive adhesive.

13. The solar panel defined in claim 11, wherein the transparent adhesive material is a polymeric sheet material.

14. The solar panel defined in claim 1, wherein when subjected to 1000 Taber abrader cycles, the coverplate material exhibits no more than 2% haze as measured on a Gardner Hazegard.

15. The solar panel defined in claim 1, wherein the photovoltaically functional material deposited on the base member is one or more chosen from the group consisting of cadmium-telluride, amorphous silicon, germanium, copper indium diselenide, and copper indium gallium selenide.

16. The solar panel defined in claim 15, wherein the photovoltaically functional materials are deposited by a process chosen from the group consisting of: chemical vapor deposition, sputtering or other vacuum techniques, physical vapor deposition spray pyrolysis and combinations thereof.

17. The solar panel defined in claim 9, wherein the electrically conductive structure is chosen from the group consisting of silver, copper and mixtures thereof.

18. The solar panel defined in claim 1, wherein a functional coating is disposed on the major surface of the glass coverplate exposed to the environment.

19. The solar panel defined in claim 18, wherein the functional coating is one or more chosen from the group consisting of: a photocatalytic coating, an anti-reflective coating, a hydrophobic coating and an electrically conductive coating.

20. The solar panel defined in claim 3, wherein the stainless steel is one chosen from the group consisting of: 308, 316, 329, and 330.

21. The solar panel defined in claim 13, wherein the coverplate and base member adhesively bonded by the polymeric sheet material comprises a laminate.

22. An insulated glass unit comprising:
a first transparent glass sheet and a second transparent glass sheet, each glass sheet having first and second major surfaces, the first and second glass sheets being in a parallel, spaced apart relationship and each having a permeability of less than 1×10⁻²¹ cm/sec;
the first glass sheet having adhered to the second major surface thereof, a base member having a permeability less than 1×10⁻²¹ cm/sec and a 0.2% yield strength of at least 205 MPa; and
in an orientation generally perpendicular to the first and second glass sheets and extending therebetween so as to be in sealing contact, at the upper and lower extent thereof, with the second major surface of the first glass sheet, and the first major surface of the second glass sheet, a frame member, a spacer, and one or more sealing members, extending around the periphery between the first and second glass sheets.

23. The insulated glass unit defined in claim 22, wherein an electrical fitting is attached to the frame/spacer thus allowing passage of one or more electrical leads from the interior of the insulated glass unit to the exterior thereof.

24. A method of making a solar panel assembly comprising:
providing a continuous ribbon of a flexible metal material having two major surfaces and a peripheral edge therearound;
in a first location, depositing one or more photovoltaically functional coating layers on at least one of the major surfaces of the continuous ribbon of flexible metal material;
cutting the continuous ribbon of coated flexible metal material into predetermined lengths and forming same into rolls of a predetermined length;
transporting the rolls of coated flexible metal material to at least a second location remote from the first location;
in at least the second location, cutting the coated flexible metal material into lengths for forming a base member of a solar panel assembly;
in the second location adhesively affixing a transparent coverplate to the coated major surface of the base member;
attaching at least one electrical connector to the adhesively bonded coverplate and base member so as to be in electrical connectivity with the photovoltaically functional coating to form a solar panel assembly; and
transporting the solar panel assembly to at least a third location remote from the at least second location whereby the solar panel assembly is put into operation.
